(19) United States
(12) Patent Application Publication
(10) Pub. No.: US 2025/0273911 A1
(43) Pub. Date: Aug. 28, 2025

(54) Shield Contact System

(71) Applicant: TE Connectivity Solutions GmbH, Schaffhausen (CH)

(72) Inventors: Michael S. Glick, Winston Salem, NC (US); William John Remaley, Winston Salem, NC (US); Ba Pham, Winston Salem, NC (US)

(73) Assignee: TE Connectivity Solutions GmbH, Schaffhausen (CH)

(21) Appl. No.: 18/589,616

(22) Filed: Feb. 28, 2024

(51) Int. Cl. H01R 13/6582; H01R 13/50; H01R 13/629

(52) U.S. Cl. CPC H01R 13/6582; H01R 13/50; H01R 13/629

(57) ABSTRACT

A shield contact system includes a first shield and a second shield. The first shield has a first shield body with a first leading edge and a guiding element extending from the first leading edge along an insertion direction. The second shield has a second shield body defining a receiving space. The second shield body has a second leading edge. The first shield and the second shield are inserted together along the insertion direction to an inserted state in which the guiding element is positioned within the receiving space and the first leading edge is separated from the second leading edge along the insertion direction. The first leading edge does not overlap the second leading edge along the insertion direction in the inserted state.

### FIELD OF THE INVENTION

The present invention relates to a contact system and, more particularly, to a contact system connecting a first shield to a second shield.

### BACKGROUND

In a shield contact system, a male shield is inserted into a female shield to form a connection between the shields. The female shield has a contact beam that extends into the space in which the male shield is received. The contact beam contacts an outer surface of the male shield to form the connection and slides along the outer surface of the male shield during insertion of the male shield.

During insertion, it can be difficult to align the male shield in the female shield, leading to stubbing of an end of the male shield on the end of the female shield and resulting in damage to the shields. Providing a larger radial gap between the male shield and the female shield can simplify the alignment in the initial mating, but allows for greater floating between the male shield and the female shield in the mated state, which decreases the stability of the electrical connection and can cause excessive wear on the contact surfaces. A male shield that is not properly aligned within the female shield and floats within the female shield leads to uneven deflection of the contact beams and poor connection between the shields. These factors limit the number of mating cycles in the usable life of the shield contact system.

### SUMMARY

A shield contact system includes a first shield and a second shield. The first shield has a first shield body with a first leading edge and a guiding element extending from the first leading edge along an insertion direction. The second shield has a second shield body defining a receiving space. The second shield body has a second leading edge. The first shield and the second shield are inserted together along the insertion direction to an inserted state in which the guiding element is positioned within the receiving space and the first leading edge is separated from the second leading edge along the insertion direction. The first leading edge does not overlap the second leading edge along the insertion direction in the inserted state.

### BRIEF DESCRIPTION OF THE DRAWINGS

The invention will now be described by way of example with reference to the accompanying Figures, of which:

FIG. 1 is a perspective view of a shield contact system according to an embodiment;

FIG. 2 is a perspective view of a first shield of the shield contact system;

FIG. 3 is a perspective view of a second shield of the shield contact system with a dielectric in the second shield;

FIG. 4 is a sectional side view of the shield contact system in an inserted state;

FIG. 5 is a sectional end view of the shield contact system in the inserted state;

FIG. 6 is a sectional side view of the shield contact system in a mated state; and

FIG. 7 is a sectional end view of the shield contact system in the mated state.

### DETAILED DESCRIPTION OF THE EMBODIMENTS

Exemplary embodiments of the present disclosure will be described hereinafter in detail with reference to the attached drawings, wherein like reference numerals refer to like elements. The present disclosure may, however, be embodied in many different forms and should not be construed as being limited to the embodiments set forth herein; rather, these embodiments are provided so that the present disclosure will convey the concept of the disclosure to those skilled in the art. In addition, in the following detailed description, for purposes of explanation, numerous specific details are set forth to provide a thorough understanding of the disclosed embodiments. However, it is apparent that one or more embodiments may also be implemented without these specific details.

Throughout the drawings, only one of a plurality of identical elements may be labeled in a figure for clarity of the drawings, but the detailed description of the element herein applies equally to each of the identically appearing elements in the figure. Throughout the specification, directional descriptors are used such as “circumferential direction,” “insertion direction,” and “radial direction”. These descriptors are merely for clarity of the description and for differentiation of the various directions. These directional descriptors do not imply or require any particular orientation of the disclosed elements.

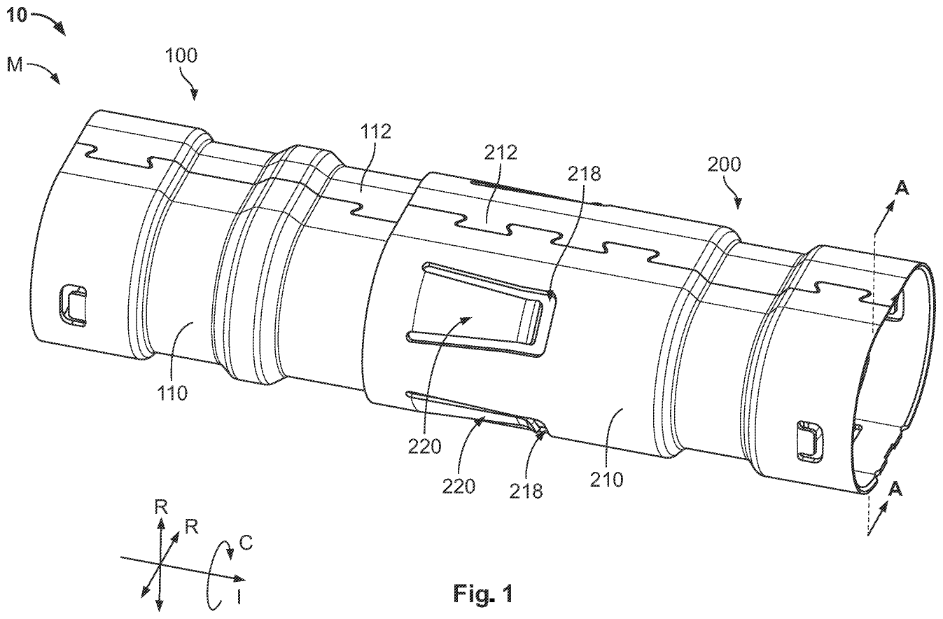

A shield contact system 10 according to an embodiment is shown in a mated state M in FIG. 1. The shield contact system 10 includes a first shield 100 and a second shield 200 that is matable with the first shield 100 along an insertion direction I.

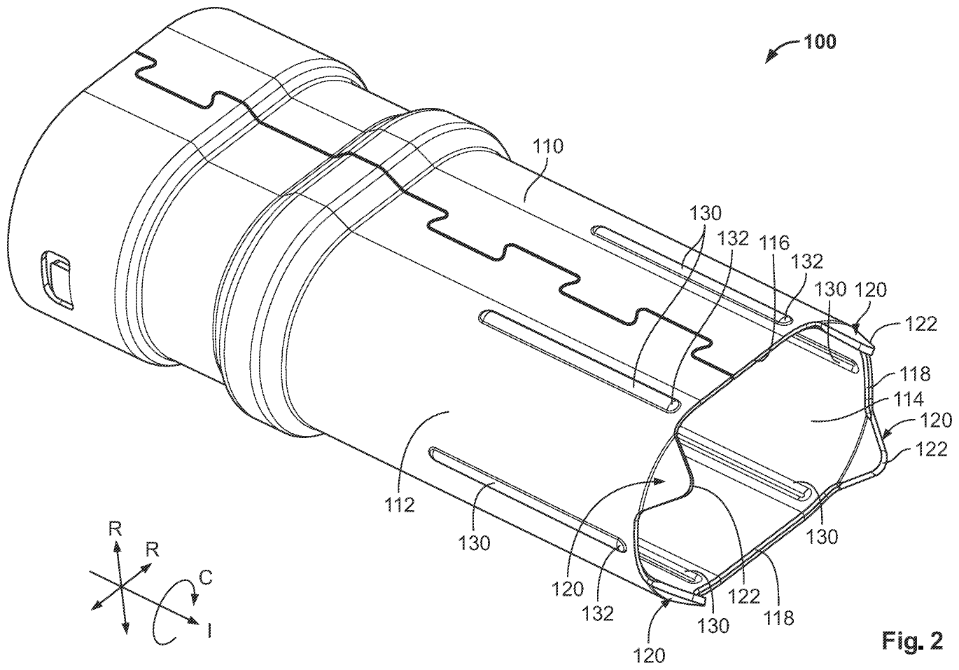

The first shield 100, as shown in FIG. 2, has a first shield body 110, a plurality of guiding elements 120 extending from the first shield body 110, and a plurality of ribs 130 extending from the first shield body 110.

As shown in FIG. 2, the first shield body 110 has a first exterior surface 112 and a first interior surface 114 opposite the first exterior surface 112 in a radial direction R perpendicular to the insertion direction I. The first shield body 110 has a first leading edge 116 at one end in the insertion direction I. In the shown embodiment, the first shield body 110 has a rounded- rectangular cross-sectional shape. In other embodiments, the first shield body 110 could have a circular cross-sectional shape, or any other cross-sectional shape used in shield contacts.

The guiding elements 120 each extend from the first leading edge 116 of the first shield body 110 in the insertion direction I, as shown in FIG. 2. The guiding elements 120 each have a guiding end 122 opposite the first leading edge 116 in the insertion direction I. In the shown embodiment, the guiding elements 120 each have an approximately triangular shape and the guiding end 122 of the guiding elements 120 has a curved shape. In other embodiments, the guiding elements 120 could have other shapes and the guiding ends 122 may or may not be curved.

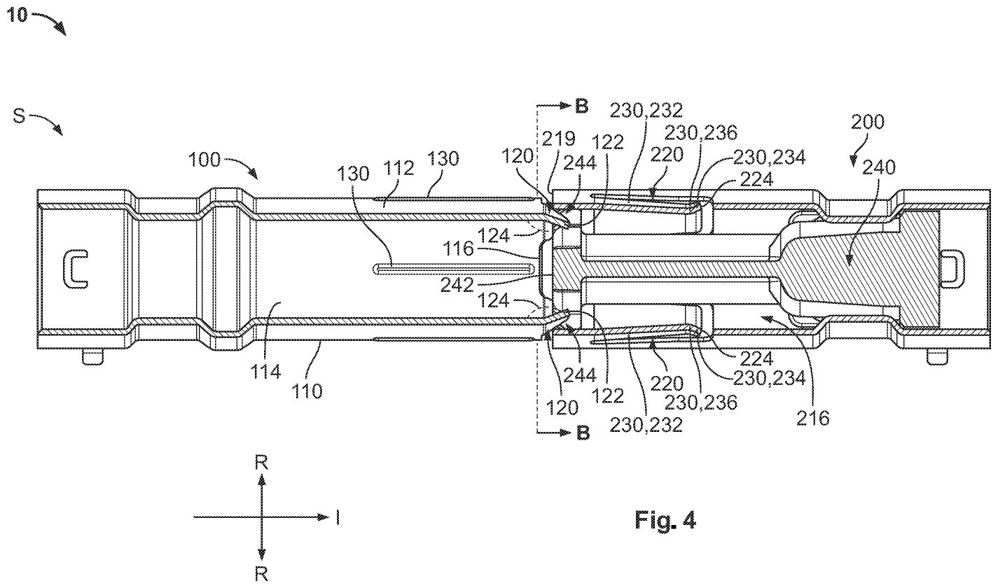

The guiding elements 120 each extend from the first leading edge 116 at a guiding angle 124 with respect to the first interior surface 114, as shown in FIG. 4. In the shown embodiment, the guiding angle 124 is an obtuse angle.

The guiding elements 120 are distributed in a circumferential direction C around the first shield body 110. In the shown embodiment, four guiding elements 120 are distributed around the first shield body 110. This embodiment is merely exemplary and, in other embodiments, less than four or more than four guiding elements 120 may be distributed around the first shield body 110 and may be arranged differently than in the positions shown in FIG. 2.

The first shield body 110 has a chamfer 118 on the first leading edge 116 between the guiding elements 120 that are distributed around the first leading edge 116, as shown in FIG. 2. The chamfer 118 is angled between the first leading edge 116 and the first interior surface 114 of the first shield body 110. In the shown embodiment, the chamfer 118 is formed on all portions of the first leading edge 116 between the guiding elements 120. In other embodiments, the chamfer 118 may be formed on only some of the portions of the first leading edge 116 between the guiding elements 120, or may be omitted.

The ribs 130 each extend from the first exterior surface 112 of the first shield body 110 in the radial direction R, as shown in FIG. 2. The ribs 130 each have a leading end 132 in the insertion direction I. The leading ends 132 of the ribs 130 are each positioned adjacent to the first leading edge 116 but spaced apart from the first leading edge 116 along the insertion direction I. In the shown embodiment, the ribs 130 are each continuous along the insertion direction I. In other embodiments, the ribs 130 may each be a series of segments separated from one another along the insertion direction I.

The ribs 130 are distributed in the circumferential direction C around the first shield body 110. In the shown embodiment, six ribs 130 are distributed around the first shield body 110. This embodiment is merely exemplary and, in other embodiments, less than six or more than six ribs 130 may be distributed around the first shield body 110 and may be arranged differently than in the positions shown in FIG. 2.

The first shield 100 is formed of a conductive material, such as aluminum. In the shown embodiment, the first shield 100 is monolithically formed in a single piece from the conductive material with the first shield body 110, the guiding elements 120, and the ribs 130; in this embodiment, the guiding elements 120 may be formed by punching in a sheet with the first shield body 110, the ribs 130 may be embossed on the first shield body 110, and the first shield body 110 may be bent into the shape shown in FIG. 2. In other embodiments, the first shield body 110 may be formed separately and attached together with the guiding elements 120 and the ribs 130.

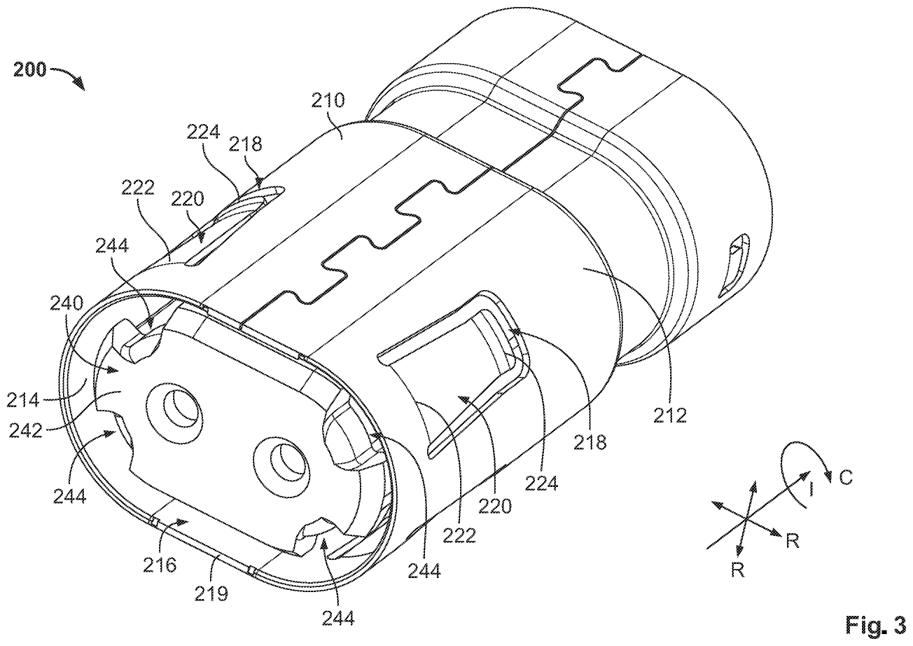

The second shield 200, as shown in FIG. 3, has a second shield body 210 and a plurality of contact beams 220 extending from the second shield body 210.

As shown in FIG. 3, the second shield body 210 has a second exterior surface 212 and a second interior surface 214 opposite the second exterior surface 212 in the radial direction R. The second shield body 210 defines a receiving space 216 extending along the insertion direction I and has a plurality of beam openings 218 extending through the second shield body 210 in the radial direction R and communicating with the receiving space 216. The second shield body 210 has a second leading edge 219 at one end in the insertion direction I. The second shield body 210 defines the receiving space 216 with a shape corresponding to the shape of the first shield body 110. In the shown embodiment, the second shield body 210 defines the receiving space 216 with a rounded-rectangular cross-sectional shape in the shown embodiment. In other embodiments, the second shield body 210 could define the receiving space 216 as a circular cross-sectional shape, or any other cross-sectional shape corresponding to the first shield body 110 and used in shield contacts.

The contact beams 220 are each positioned in one of the beam openings 218, as shown in FIG. 3. The contact beams 220, in the shown embodiment, are each cantilevered from the second shield body 210 and extend from a fixed end 222 to a cantilevered end 224 along the insertion direction I. In the shown embodiment, the cantilevered end 224 is positioned further from the second leading edge 219 of the second shield body 210 than the fixed end 222 along the insertion direction I. In another embodiment, the contact beam 220 may extend in the reverse direction with the cantilevered end 224 positioned close to the second leading edge 219 than the fixed end 222 along the insertion direction I. In other embodiments, the contact beams 220 may be connected at both ends but otherwise function as described herein.

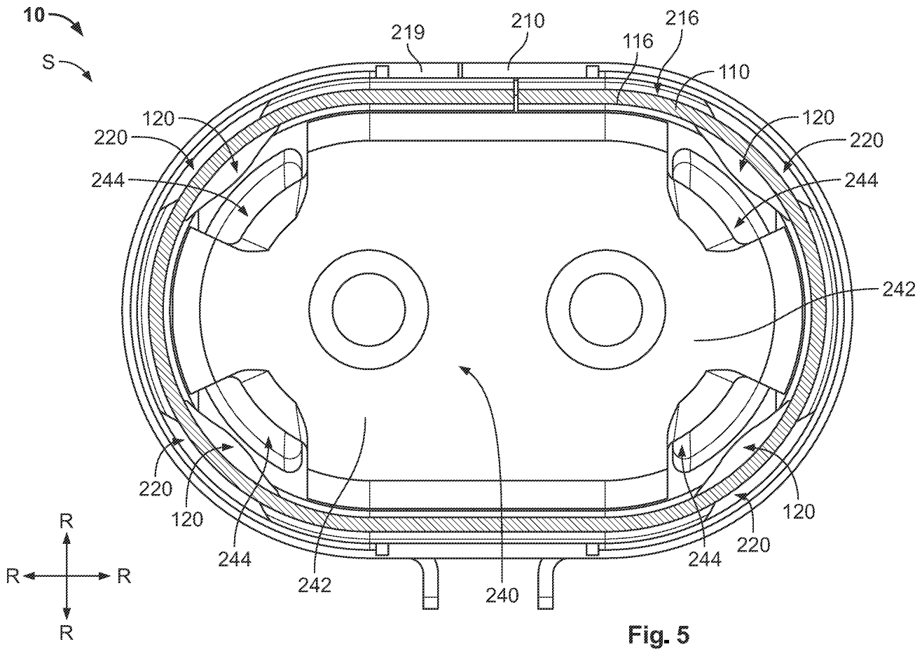

Each of the contact beams 220 has a beam body 230, as shown in FIGS. 4 and 5. The beam body 230 has a first beam section 232 and a second beam section 234 connected to the first beam section 232 at a contact point 236. The second beam section 234 is bent at an angle with respect to the first beam section 232; the angle of the second beam section 234 with respect to the first beam section 232 is greater than 90° and less than 180°. The contact point 236 is positioned at the intersection of the first beam section 232 and the second beam section 234. The contact point 236 is spaced apart from the cantilevered end 224 along the insertion direction I.

The contact beams 220, as shown in FIG. 3, are distributed in the circumferential direction C around the second shield body 210. In the shown embodiment, four contact beams 220 are distributed around the second shield body 210. This embodiment is merely exemplary; the number of contact beams 220 of the second shield 200 and the location of the contact beams 220 on the second shield 220 in the circumferential direction C corresponds to the number of guiding elements 120 of the first shield 100 and the locations of the guiding elements 120 on the first shield 100 in the circumferential direction C.

The second shield 200 is formed of a conductive material, such as aluminum. In the shown embodiment, the second shield 200 is monolithically formed in a single piece from the conductive material with the second shield body 210 and the contact beams 220. The second shield body 210 may be formed in a sheet, with the contact beams 220 punched and embossed, and then bent into the shape shown in FIG. 3. In other embodiments, the second shield body 210 may be formed separately and attached together with the contact beams 220.

In the embodiment shown in FIG. 3, a dielectric 240 is positioned within the receiving space 216 of the second shield 200. The dielectric 240 has a mating face 242 facing opposite to the insertion direction I. The dielectric 240 has a plurality of cutouts 244 at sides of the mating face 242. In the shown embodiment, the dielectric 240 has four cutouts 244 distributed around the dielectric 240 in the circumferential direction C. This embodiment is merely exemplary; the number of cutouts 244 and the location of the cutouts 244 on the dielectric 240 in the circumferential direction C corresponds to the number of guiding elements 120 of the first shield 100 and the locations of the guiding elements 120 on the first shield 100 in the circumferential direction C.

The mating of the first shield 100 and the second shield 200 to form the connection of the shield contact system 10 will now be described in greater detail primarily with respect to FIGS. 4-7.

The first shield 100 and the second shield 200 are inserted together along the insertion direction I. The first shield 100 and the second shield 200 initially reach an inserted state S shown in FIG. 4 along the insertion direction I. In the inserted state S, the guiding features 120 are positioned within the receiving space 216 of the second shield body 210 and the first leading edge 116 is separated from the second leading edge 219 along the insertion direction I; the guiding features 120 enter the receiving space 216 before the leading edges 116, 219 reach one another along the insertion direction I.

When the first shield 100 and the second shield 200 reach the inserted state S, the guiding features 120 align the first shield 100 within the second shield 200 for further insertion along the insertion direction I. The guiding angle 124 of the guiding elements 120 and the protrusion of the guiding elements 120 beyond the first leading edge 116 assist a user in positioning the guiding elements 120 within the receiving space 216 at the second leading edge 219 and prevent stubbing or direct contact between the leading edges 116, 219 during insertion. In the inserted state S, as shown in FIG. 5, the first shield body 110 is aligned by the guiding elements 120 within the receiving space 216 of the second shield body 210 and the first leading edge 116 does not overlap the second leading edge 219.

As shown in FIGS. 4 and 5, the guiding elements 120 have entered and are positioned within the cutouts 244 of the dielectric 240 in the inserted state S. The cutouts 244 permit the alignment provided by the guiding elements 120 without having the dielectric 240 impede the movement of the guiding elements 120 and the first shield 100 along the insertion direction I.

The first shield 100 and the second shield 200 are inserted further together along the insertion direction I from the inserted state S to a mated state M shown in FIGS. 1, 6, and 7.

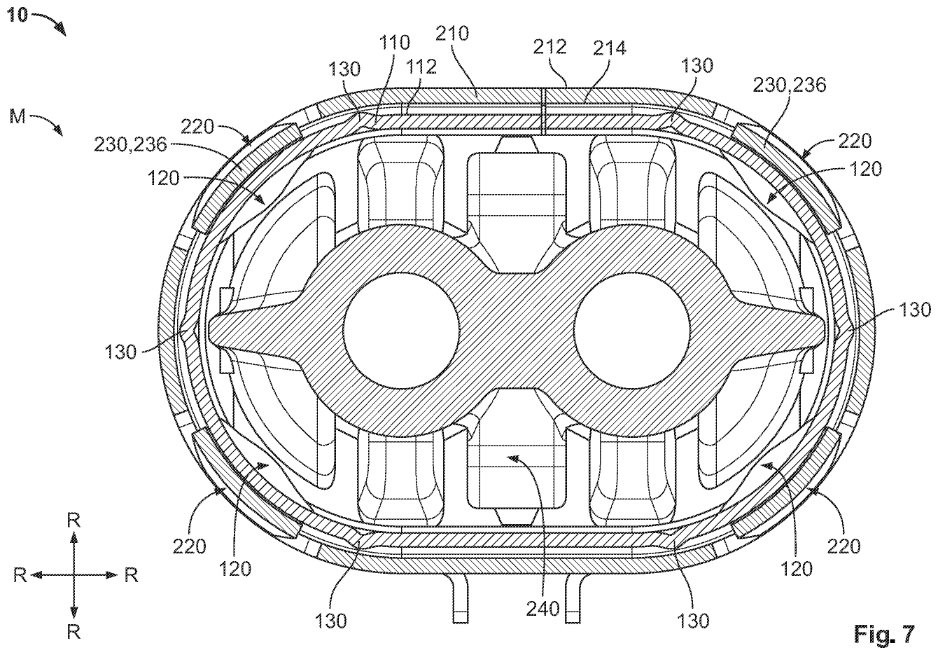

As the shields 100, 200 move together between the inserted state S and the mated state M, the first leading edge 116 first enters the receiving space 216 at the second leading edge 219 and the ribs 130 then enter the receiving space 216. The ribs 130 protruding from the first exterior surface 112 of the first shield body 110 are positioned between the first shield body 110 and the second shield body 210 as the shields 100, 200 move together along the insertion direction I from a position after the inserted state S to the mated state M shown in FIG. 7. The ribs 130 lessen the gap between the second interior surface 214 of the second shield body 210 and the first exterior surface 112 of the first shield body 110 in the radial direction R, providing stability between the connection between the first shield 100 and the second shield 200 in the mated state M and centering the first shield 100 in the receiving space 216.

The guiding elements 120 are each aligned with one of the contact beams 220 along the insertion direction I, as shown in FIGS. 4-6. From the inserted state S to the mated state M along the insertion direction I, the guiding elements 120 pass through the cutouts 244 of the dielectric 240 and then initially contact the contact beams 220 at the fixed end 222. The guiding elements 120 of the first shield 100 contact the contact beams 220 after aligning the first shield 100 within the second shield 200 as the shields 100, 200 move together along the insertion direction I.

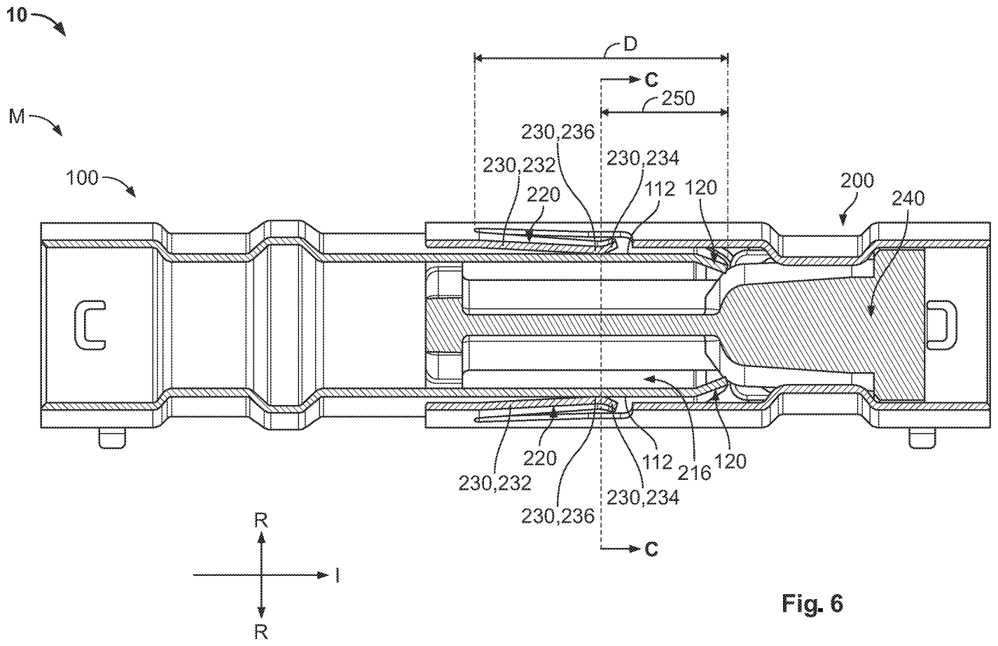

As shown in FIGS. 4 and 6, as the shields 100, 200 move together along the insertion direction I, the guiding elements 120 each contact and move along one of the contact beams 220, deflecting the contact beam 220 away from the first shield body 110 and away from the receiving space 216 in the radial direction R. The guiding end 122 of the guiding element 120 having a curved shape prevents damage to the contact beam 220 at initial contact and the guiding angle 124 of the guiding element 120 forms an angled outer surface for a gradual progressive deflection of the contact beam 220 as the first shield 100 moves along the insertion direction I. The shown embodiment of the contact beam 220 in which the cantilevered end 224 is positioned further from the second leading edge 219 than the fixed end 222 further limits damaging contact between the guiding element 120 and the contact beam 220 and provides for a more gradual deflection of the contact beam 220 by the first shield 100.

The contact beam 220 is at a maximum deflection when the contact point 236 has passed the guiding element 120 and is in contact with the first exterior surface 112 of the first shield body 110. As the shields 100, 200 are further inserted together along the insertion direction I to the mated state M shown in FIG. 6, the contact point 236 slides along the first exterior surface 112 of the first shield body 110 by a wiping distance 250. In the mated state M, as shown in FIGS. 6 and 7, the contact points 236 of the contact beams 220 abut the first exterior surface 112 of the first shield body 110 and form the connection between the first shield 100 and the second shield 200.

The shield contact system 10 described above and shown in the drawings is one possible embodiment that incorporates the features of the invention. In another embodiment, for example, the ribs 130 can be positioned on the second shield 200 and extend from the second interior surface 214 into the receiving space 216.

In the mated state M, the first shield 100 and the second shield 200 are electrically connected. The shield contact system 10 may be part of an electrical connector system that electrically connects electrical components. In this application, the first shield 100 is positioned around a first dielectric having a first contact and the dielectric 240 is a second dielectric in the second shield 200 that has a second contact. The first shield 100 and the second shield 200 move into the mated state M described above to provide electromagnetic shielding for the mating between the first contact and the second contact.

In the shield contact system 10 according to the embodiments described above, the guiding elements 120 provide alignment of the first shield 100 within the second shield 200 that cases mating of the shields 100, 200 along the insertion direction I and prevents stubbing of the leading edges 116, 219. The ribs 130 lessen the radial gap between the shields 100, 200 in the mated state M, which decreases floating between the shields 100, 200 and provides centering, limiting wear from floating movement and providing for approximately even deflection of the contact beams 220. The embodiment of the contacts beams 220 in which the cantilevered end 224 is positioned further from the second leading edge 219 than the fixed end 222 decreases the wiping distance 250 in comparison to an exemplary wiping distance D in FIG. 6 that would occur if the contact beam 220 was reversed, further limiting the wear on the shields 100, 200. The shield contact system 10 minimizes wear and allows for the shield contact system 10 to be used over a greater number of mating cycles.

What is claimed is:

1. A shield contact system, comprising:
a first shield having a first shield body with a first leading edge and a guiding element extending from the first leading edge along an insertion direction; and
a second shield having a second shield body defining a receiving space, the second shield body has a second leading edge, the first shield and the second shield are inserted together along the insertion direction to an inserted state in which the guiding element is positioned within the receiving space and the first leading edge is separated from the second leading edge along the insertion direction, the first leading edge does not overlap the second leading edge along the insertion direction in the inserted state.

2. The shield contact system of claim 1, wherein the second shield has a contact beam extending from the second shield body.

3. The shield contact system of claim 2, wherein the first shield and the second shield are inserted together along the insertion direction from the inserted state to a mated state, the contact beam abuts the first shield body in the mated state.

4. The shield contact system of claim 3, wherein the guiding element contacts and deflects the contact beam during insertion along the insertion direction between the inserted state and the mated state.

5. The shield contact system of claim 2, wherein the guiding element is one of a plurality of guiding elements distributed around the first leading edge in a circumferential direction and the contact beam is one of a plurality of contact beams distributed around the second shield body in the circumferential direction.

6. The shield contact system of claim 5, wherein each of the guiding elements is aligned with one of the contact beams along the insertion direction.

7. The shield contact system of claim 1, wherein the guiding element extends from the first leading edge at an obtuse angle with respect to a first interior surface of the first shield body.

8. The shield contact system of claim 1, wherein a guiding end of the guiding element in the insertion direction has a curved shape.

9. The shield contact system of claim 1, wherein the guiding element has an approximately triangular shape.

10. The shield contact system of claim 1, wherein the guiding element is monolithically formed in a single piece with the first shield body.

11. The shield contact system of claim 1, wherein the guiding element is one of a plurality of guiding elements distributed around the first leading edge in a circumferential direction, the first shield body has a chamfer on the first leading edge between the guiding elements.

12. The shield contact system of claim 1, wherein the first shield has a rib extending from the first shield body, the rib is positioned between the first shield body and the second shield body in a mated state of the first shield and the second shield.

13. The shield contact system of claim 12, wherein a leading end of the rib is spaced apart from the first leading edge along the insertion direction.

14. The shield contact system of claim 2, wherein the contact beam is cantilevered from the second shield body and extends from a fixed end to a cantilevered end along the insertion direction.

15. The shield contact system of claim 14, wherein the cantilevered end is positioned further from a second leading edge of the second shield body than the fixed end along the insertion direction.

16. The shield contact system of claim 1, further comprising a dielectric positioned within the receiving space, the dielectric has a mating face with a cutout, the guiding element passes through the cutout during insertion along the insertion direction.

17. A process of connecting a shield contact system, comprising:
providing a first shield having a first shield body with a first leading edge and a guiding element extending from the first leading edge along an insertion direction;
providing a second shield having a second shield body defining a receiving space, the second shield body has a second leading edge; and
inserting the first shield and the second shield together along the insertion direction to an inserted state in which the guiding element is positioned within the receiving space and the first leading edge is separated from the second leading edge along the insertion direction, the guiding element aligns the first shield within the second shield as the first shield and second shield are further inserted together along the insertion direction from the inserted state.

18. The process of claim 17, wherein the first shield and the second shield are inserted together along the insertion direction from the inserted state to a mated state, the second shield has a contact beam extending from the second shield body and contacting the first shield body in the mated state, the guiding element aligns the first shield within the second shield during insertion along the insertion direction before the contact beam contacts the first shield body.

19. The process of claim 18, wherein the contact beam is cantilevered from the second shield body and extends from a fixed end to a cantilevered end along the insertion direction, the guiding element contacts the fixed end before the cantilevered end and deflects the contact beam during insertion from the inserted state to the mated state.

20. The process of claim 17, wherein the first shield has a rib extending from the first shield body, the rib centers the first shield within the receiving space.
